(19) United States
(12) Patent Application Publication
(10) Pub. No.: US 2012/0309188 A1
(43) Pub. Date: Dec. 6, 2012

(54) METHOD TO IMPROVE ADHESION FOR A SILVER FILLED OXIDE VIA FOR A NON-VOLATILE MEMORY DEVICE

(75) Inventor: Scott Brad HERNER, San Jose, CA (US)

(73) Assignee: Crossbar, Inc., Santa Clara, CA (US)

(21) Appl. No.: 13/149,653

(22) Filed: May 31, 2011

(51) Int. Cl. H01L 21/768

(52) U.S. Cl. 438/624; 257/E21.575

(57) ABSTRACT

A method for forming an interconnect structure for a memory device. The method includes providing a partially fabricated device. The partially fabricated device includes a switching element overlying a first wiring structure. A thickness of dielectric material is deposited overlying the first wiring structure. The method deposits an adhesion material overlying the thickness of the dielectric material. A via opening is formed in a portion of the thickness of the dielectric material to expose a surface region of the switching element while the adhesion material is maintained overlying the dielectric material. A second wiring material is deposited overlying the thickness of the dielectric material and to fill at least part of the via opening and forming a thickness of second wiring material overlying the adhesion material. The adhesion material maintains the second wiring material to be adhered to the surface region of the thickness of the dielectric material.

### CROSS REFERENCE TO RELATED APPLICATIONS

The application is related to application Ser. No. 12/835,704, filed Jul. 13, 2010, application Ser. No. 12/835,699, filed Jul. 13, 2010, application Ser. No. 12/861,650, filed Aug. 23, 2010, Application No. 61/428,982, filed Dec. 31, 2010, and Application No. 61/428,994, filed Dec. 31, 2010, commonly assigned, and incorporated by reference for all purpose hereby.

### STATEMENTS RELATED TO GOVERNMENT OR FEDERALLY FUNDED RESEARCH

Not Applicable

### BACKGROUND

The present invention is generally related to resistive switching devices. More particularly, embodiments according to the present invention provide a method and a structure for forming an interconnect structure for a resistive switching device. The present invention can be applied to non-volatile memory devices but it should be recognized that the present invention can have a much broader range of applicability.

The success of semiconductor devices has been mainly driven by an intensive transistor down-scaling process. However, as field effect transistors (FET) approach sizes less than 100 nm, problems such as the short channel effect degrade device performance. Moreover, such sub 100 nm device sizes can lead to sub-threshold slope non-scaling and increase in power dissipation. It is generally believed that transistor-based memories such as those commonly known as Flash may approach an end to scaling within a decade. Flash memory is one type of non-volatile memory device.

Other non-volatile random access memory (RAM) devices such as ferroelectric RAM (Fe RAM), magneto-resistive RAM (MRAM), organic RAM (ORAM), and phase change RAM (PCRAM), among others, have been explored as next generation memory devices. These devices often require new materials and device structures to couple with silicon-based devices to form a memory cell, which lack one or more key attributes. For example, Fe-RAM and MRAM devices have fast switching characteristics and good programming endurance, but their fabrication is not CMOS compatible and size is usually large. Switching a PCRAM device requires a large amount of power. Organic RAM or ORAM is incompatible with large volume silicon-based fabrication and device reliability is usually poor.

From the above, a new semiconductor device structure and integration is desirable.

### BRIEF SUMMARY OF THE PRESENT INVENTION

The present invention is generally related to resistive switching devices. More particularly, embodiments according to the present invention provide a method and a structure for forming an interconnect structure for a resistive switching device. The present invention can be applied to non-volatile memory devices but it should be recognized that the present invention can have a much broader range of applicability.

In a specific embodiment, a method for forming an interconnect structure for a memory device is provided. The method includes providing a semiconductor substrate having a surface region and depositing a thickness of first dielectric material overlying the surface region of the semiconductor substrate. A plurality of first wiring structures are formed in a portion of the first thickness of the first thickness of dielectric material. Each of the plurality of first wiring structures includes at least a surface region. The method includes forming a switching material overlying the surface region of each of the first wiring structures and depositing a thickness of second dielectric material overlying at least the surface region of the first plurality of first wiring structure. In a specific embodiment, the method includes depositing an adhesion material overlying the thickness of the second dielectric material. The method includes forming a via opening in a portion of the thickness of the second dielectric material to expose a surface region of the switching material while maintaining the adhesion material overlying the second dielectric material in a specific embodiment. A second wiring material is formed overlying a surface region of the thickness of the second dielectric material and to fill at least part of the via opening and forming a thickness of second wiring material overlying the adhesion material while the adhesion material maintaining the second wiring material to be adhered to the surface region of the thickness of the second dielectric material.

In a specific embodiment, a method of forming an interconnect for a non-volatile memory device is provided. The method includes providing a switching material comprising an amorphous silicon material and forming a thickness of a dielectric material overlying the switching material. The method includes depositing an adhesion material overlying the thickness of the dielectric material. A via opening is formed in a first portion of the thickness of the dielectric material to expose a surface region of the switching material while the adhesion material remained overlying a second portion of the thickness of dielectric material in a specific embodiment. The method deposits a metal material to fill the via opening and to form a thickness of metal material overlying the adhesion material. The metal material is in contact with the switching material. The method includes subjecting the metal material to a patterning and etching process to form an interconnect structure while maintaining the metal material in the via opening to be in contact with the switching material and the metal material to be in contact with the adhesion material in a specific embodiment.

Many benefits can be achieved by ways of the present invention over conventional techniques. For example, embodiments according to the present invention provide a method and a structure to form a wiring structure for a non-volatile memory device. The wiring structure is characterized by a high conductivity and a good adhesion characteristic to provide for a high density crossbar array of memory cells in a specific embodiment. Additionally, the wiring structure can be formed without modification to conventional equipments and deposition techniques. Depending on the embodiment, one or more of these benefits may be achieved. One skilled in the art would recognize other modifications, variations and alternatives.

### SUMMARY OF THE DRAWINGS

FIGS. 1-10 are simplified diagrams illustrating a method of forming an interconnect structure for a non-volatile memory device according to an embodiment of the present invention.

FIGS. 11-13 are simplified diagrams illustrating an alternative method of forming an interconnect structure for a non-volatile memory device according to an embodiment of the present invention.

FIGS. 14-18 are simplified diagrams illustrating a method of forming an interconnect structure for a non-volatile memory device according to an embodiment of the present invention.

### DETAILED DESCRIPTION OF THE PRESENT INVENTION

The present invention is generally related to resistive switching devices. More particularly, embodiments according to the present invention provide a method and a structure for forming an interconnect structure for a resistive switching device. Embodiments according to the present invention can be applied to non-volatile memory devices but it should be recognized that the present invention can have a much broader range of applicability.

Resistive switching behavior has been observed and studied in micro-scale amorphous silicon (a-Si) devices since the 1980s. A typical device consists of a pair of metal electrodes sandwiching an amorphous-Si layer in a so-called Metal/a-Si/Metal (M/a-Si/M) structure, in which the voltage applied across the pair of metal electrodes causes changes in the resistance of the a-Si material. These conventional M/a-Si/M based switching devices can have the advantages of high Ion/Ioff ratios, and can be fabricated with a CMOS compatible fabrication process and materials.

To further decrease cost per bit, device shrinking and process simplification is necessary. To achieve smaller device size, electrical resistance of the interconnect would have to be reduced. Silver has a low resistivity which improves device performance and therefore reduces the size of an integrated memory product (>1 Mbit). Silver has an additional advantage of having a desirable diffusivity in the amorphous silicon material in a presence of an electric field. Additionally, as silver is used in the resistive switching device, the total number of process steps can be further reduced if silver is also used as an interconnect material. Embodiments according to the present invention provide a method and a structure to form a non-volatile memory device using silver both as an interconnect and as part of the memory cell with desirable material characteristics and device reliability.

The terms “bottom” and “top” are used for reference only and are not meant to be limiting.

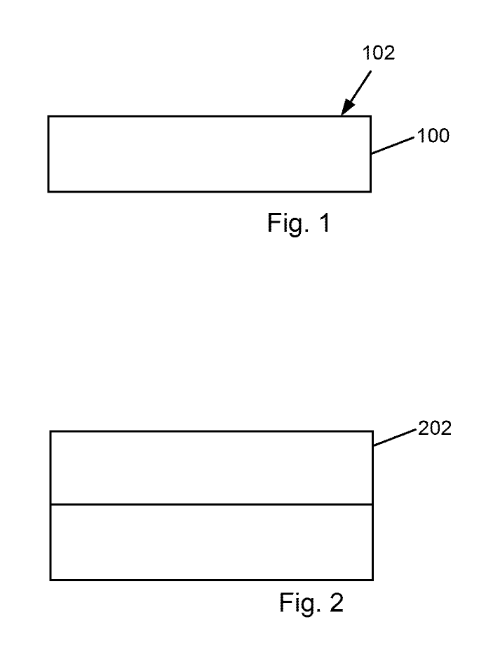

FIG. 1 illustrates a method of forming a non-volatile memory according to an embodiment of the present invention. As shown in FIG. 1, a semiconductor substrate 100 having a surface region 102 is provided. The semiconductor substrate can be a single silicon wafer, a silicon on insulator (commonly known as SOI) substrate, a silicon germanium substrate, or the like, depending on the application. In an embodiment, the semiconductor substrate further includes one or more transistor device formed thereon. The one or more transistor device can be control circuitry for the non-volatile memory device in a specific embodiment.

Referring to FIG. 2, the method includes depositing a thickness of a first dielectric material 202 overlying the surface region of the semiconductor substrate. The first dielectric material can be silicon oxide, silicon nitride, a dielectric stack having alternating layers of silicon oxide and silicon nitride (for example an ONO stack), a low K dielectric, a high K dielectric, a combination of these, or other similar materials. The first dielectric material may be deposited using techniques such as a chemical vapor deposition (CVD) process, a physical vapor deposition process, and others. The first dielectric material can be deposited using a chemical vapor deposition (CVD) process, including plasma enhanced CVD, low pressure CVD, spin on glass (SOG), or any combination of these. The silicon oxide material can be doped using boron, phosphorous, fluorine or other material or a combination of materials to provide for a suitable and desirable characteristic (for example, dielectric constant) depending on the application.

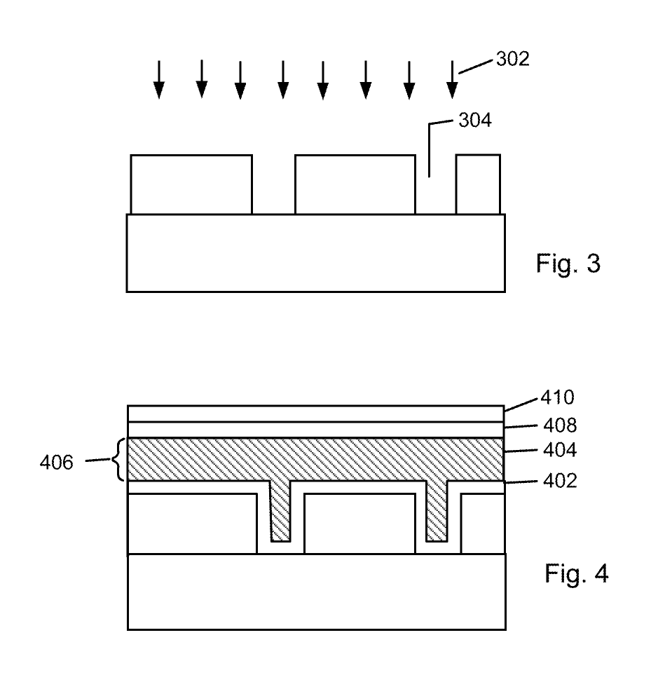

The method subjects the thickness of the first dielectric material to a first patterning and etching process 302 to form a plurality of first openings 304 as shown in FIG. 3. Referring now to FIG. 4, the method deposits a first diffusion barrier material 402 conformally overlying the plurality of first openings and a surface region of the first dielectric material in a specific embodiment. The first diffusion barrier material can be tantalum nitride, titanium, titanium nitride, tungsten nitride, including any combination thereof, and others. A first wiring material 404 is deposited to fill the plurality of first openings and to form a thickness 406 of first wiring material overlying the first dielectric material also shown in FIG. 4. The first wiring material can be tungsten, copper, aluminum, or silver depending on the embodiment. The first wiring material can be deposited using techniques such as a chemical vapor deposition process, a physical vapor deposition process, electrochemical process such as electroplating or electroless deposition, or a combination of these or similar processes, depending on the application.

Referring again to FIG. 4, the method includes depositing a contact material 408 overlying the first wiring material and a depositing a resistive switching material 410 overlying the contact material. In a specific embodiment, the resistive switching material includes an amorphous silicon material. Depending on the embodiment, the amorphous silicon material can be deposited using techniques such as low pressure CVD, plasma enhanced CVD, PVD, or others, depending on the embodiment. Deposition temperature can range from about 250 to about 400 degrees Celsius depending on the application. When amorphous silicon is used as the resistive switching material 410, the contact material 408 can be a polysilicon material having a suitable impurity characteristic. In a specific embodiment, the contact material is p+ doped polysilicon material. In other embodiments, the contact material can be a p+ doped silicon germanium material. In certain embodiments, the contact material can be optional.

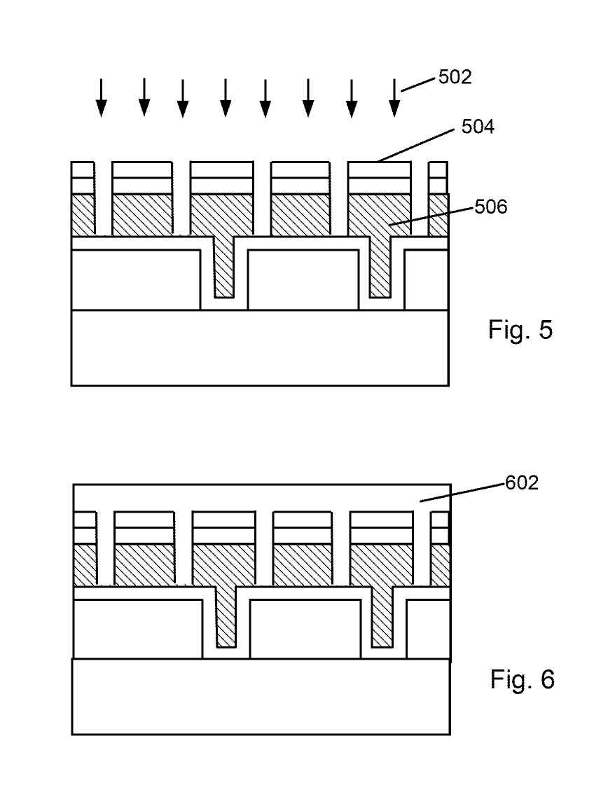

In a specific embodiment, as illustrated in FIG. 5, the method includes subjecting the resistive switching material 410, the contact material and the first wiring material to a second patterning and etching process 502 to form a plurality of first structures 504. Each of the first structures includes a first wiring structure 506 comprising at least the first wiring material 404 elongated in shape and spatially disposed in a first direction. The method may further subject the resistive switching material and the contact material to an optional third patterning and etching process to form one or more switching elements. The one or more switching elements are isolated structures to prevent disturb between the switching elements in a specific embodiment.

As shown in FIG. 6, the method deposits a second dielectric material 602 overlying the plurality of first structures and filling a gap between each of the first structures or each of the switching elements. The method further forms a thickness of second dielectric material overlying the switching material in a specific embodiment. The second dielectric material can be silicon oxide, silicon nitride, a dielectric stack having alternating layers of silicon oxide and silicon nitride (for example an ONO stack), a low K dielectric, a high K dielectric, and a combination of these, and others depending on the embodiment. The second dielectric material may be deposited using techniques such as a chemical vapor deposition process, a physical vapor deposition process, and others. The second dielectric material can be deposited using a chemical vapor deposition (CVD) process, including plasma enhanced CVD, low pressure CVD, spin on glass (SOG), or any combination of these. The silicon oxide material can be doped using boron, phosphorous, fluorine or other material or a combination of materials to provide for a suitable and desirable characteristic (for example, dielectric constant) depending on the application.

In an embodiment, the second dielectric material may be subjected to a planarizing process to form a planarized surface. The planarizing process can be a chemical mechanical polishing process, an etch back process such as a dry etch process, or a combination, depending on the application.

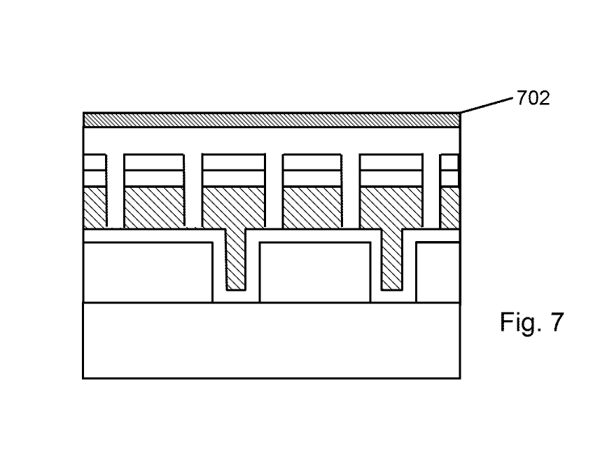

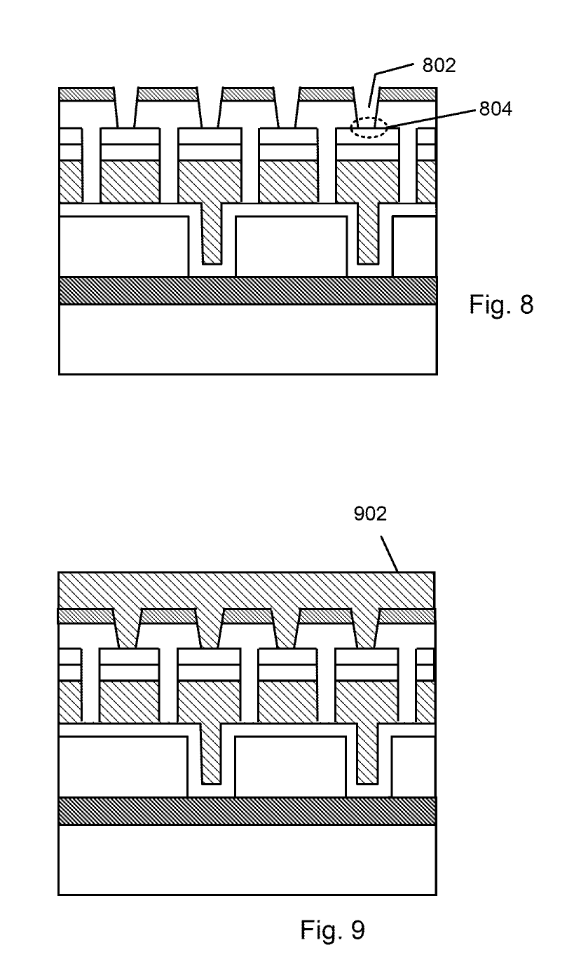

In a specific embodiment, the method includes forming a second adhesion material 702 overlying the second dielectric material as shown in FIG. 7. The second adhesion material can be titanium in a specific embodiment. Alternatively, the method can further form a titanium nitride material overlying titanium (Ti/TiN) in a specific embodiment. Other suitable adhesion material may also be used. These other adhesion materials can include tantalum overlying titanium (Ti/Ta), tantalum nitride overlying titanium (Ti/TaN), tungsten nitride overlying titanium (Ti/WN), or titanium tungsten overlying a titanium (Ti/TiW), including a combination of these, and others.

In a specific embodiment, the method includes subjecting second adhesion material to a patterning and etching process to form an opening 802 in a portion of the second adhesion material and the second dielectric material to expose a portion of a surface region 804 of the switching material in a specific embodiment. In a specific embodiment, the method can use the second adhesion material as a hard mask to form the opening in the second dielectric material.

In a specific embodiment, the method includes depositing a second wiring material 902 to fill the opening in the portion of the second dielectric material and to form a thickness of second wiring material overlying the second adhesion material. The second wiring material is in direct contact with the resistive switching material physically and electrically in a specific embodiment. The second wring material can be silver, copper, zinc, gold, platinum, palladium, nickel, and other suitable conductive material for amorphous silicon material as the resistive switching material. In certain embodiment, the second wiring material includes a silver material. The silver material may be deposited using techniques such as chemical vapor deposition, physical vapor deposition, electroplating, electroless deposition, including any combinations of these, and others, depending on the embodiment. The second adhesion material allows adhesion of the second wiring material to the second dielectric material in a specific embodiment. In a specific embodiment, the second wiring material is characterized by a suitable diffusivity in the resistive switching material in a presence of an electric field. The electric field causes a change in resistance of the resistive switching material in a specific embodiment.

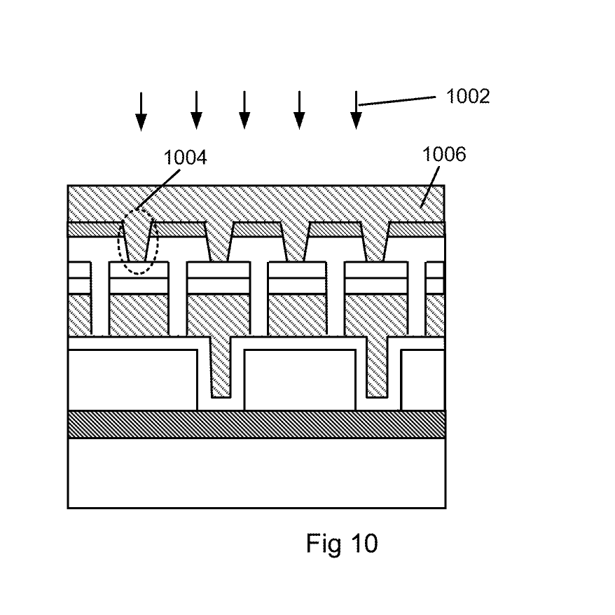

In a specific embodiment, the method subjects the second wiring material and the second adhesion material to a third pattern and etch process 1002 to form a plurality of second wiring structures overlying the resistive switching element as illustrated in FIG. 10. The second adhesion material maintains each of the second wiring structure to be in contact with a respective region of the second dielectric material in a specific embodiment. Additionally, the second wiring structure includes a first portion 1004 disposed in the via structure and in direct contact with the resistive switching material in a preferred embodiment. In a specific embodiment, each of the plurality of the second wiring structure includes a second portion 1006 spatially arranged to extend in a second direction at an angle to the first direction of the first wiring structure in a specific embodiment. In a specific embodiment, the second direction orthogonal to the first direction in a specific embodiment.

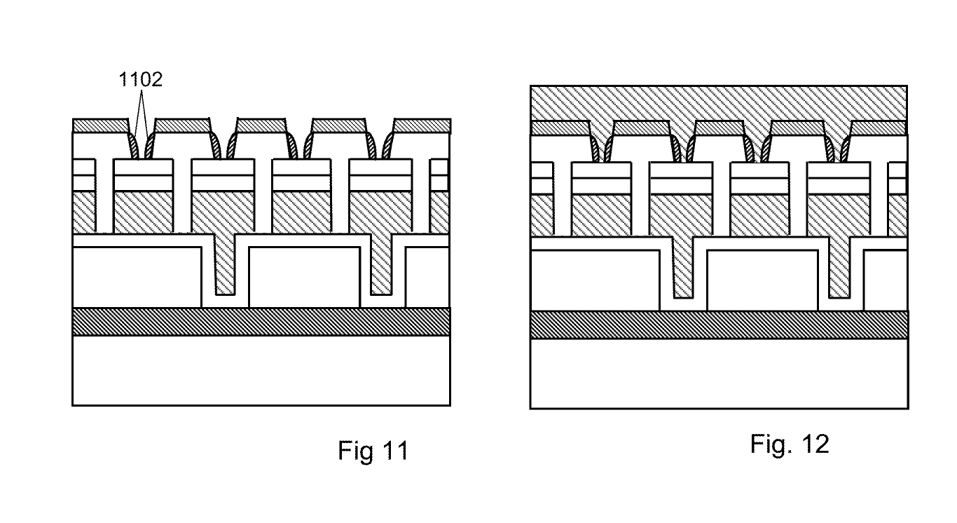

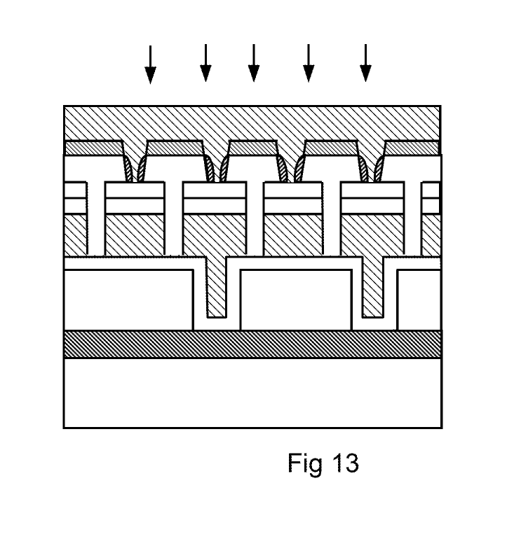

Depending on the embodiment, there can be other variations. For example, the size of the opening above the resistive switching material can have a smaller dimension by forming a dielectric sidewall structure 1102 in a portion of the via opening as shown in FIGS. 11-13. As an off-state current (Ioff) is essentially dark current or leakage current of the device, a smaller device size would result in a lower leakage current. An on-state current (Ion) is independent of the device size. Therefore, having a smaller device size by using a dielectric sidewall spacer structure 1102 would greatly improve an Ion to Ioff ratio and overall device performance.

In a specific embodiment, the second wiring material forms a metal region in a portion of the resistive switching material upon application of a bias voltage greater than a threshold voltage to the wiring structures. With a resistive switching device using silver as the second wiring material and amorphous silicon material resistive switching material (Ag/a-Si switching device) as an example. A first positive bias voltage greater than the threshold voltage applied to the second wiring structure causes a silver region to form in a portion of the amorphous silicon material and the resistive switching device is in a high resistance state such that an off state current Ioff flows in the device. The first positive bias voltage is a forming voltage for the resistive switching device, and can range from about 4 volts to about 8 volts for the Ag/a-Si switching device. The metal region further comprises a filament structure characterized by a length, a distance between silver particles, and a distance between the filament structure and the first switching structure. The filament structure extends towards the first wiring structure upon application of a second positive voltage to the second wiring structure. When the filament contacts the first wiring structure, the resistive switching device enters a low resistance state or a programmed state and an on state current Ion flows in the resistive switching device. The low resistance state is a write state for the device in a specific embodiment. When a negative bias voltage is applied to the second wiring structure after programming, the filament structure retracts and the device reverts to the high resistance erase state.

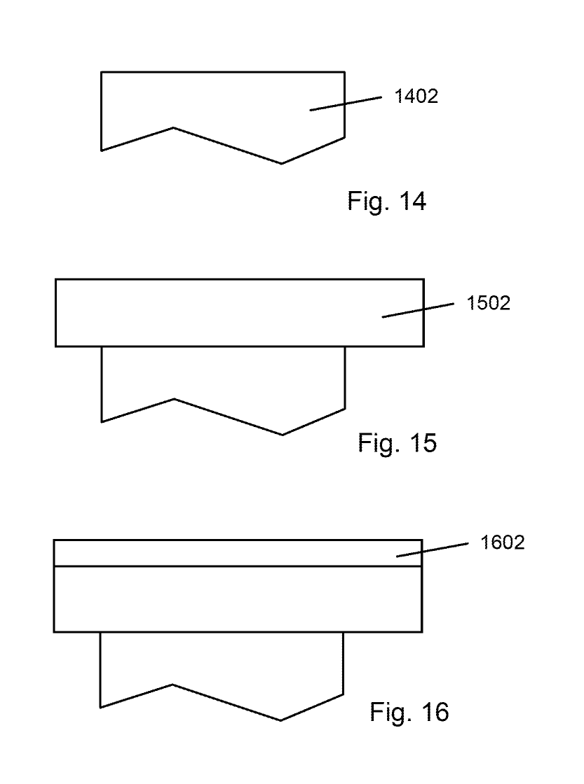

Referring to FIG. 14, a partially fabricated non-volatile memory device is provided. The partially fabricated non-volatile memory device includes a resistive switching material 1402, which can be an amorphous silicon material in a specific embodiment. The method includes depositing a dielectric material 1502 overlying the resistive switching material as shown in FIG. 15. The dielectric material can be silicon oxide, silicon nitride, a dielectric stack comprising alternating layer of silicon oxide and silicon nitride (ONO), a low K dielectric, a high K dielectric, or a combination thereof.

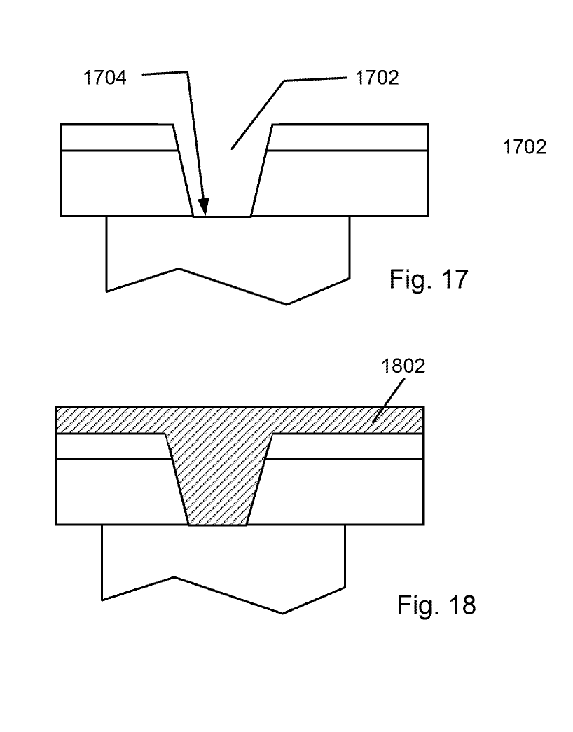

Referring to FIG. 16, the method includes depositing an adhesion material 1602 overlying the dielectric material. The adhesion material 1602 can be titanium in a specific embodiment. In another embodiment, the adhesion material can be titanium nitride overlying titanium (Ti/TiN). Other suitable adhesion materials may also be used. These other adhesion materials can include tantalum overlying titanium (Ti/Ta), tantalum nitride overlying titanium (Ti/TaN), tungsten nitride overlying titanium (Ti/WN), or titanium tungsten overlying a titanium (Ti/TiW), including a combination of these, and others. As shown in FIG. 17, the method subjects the adhesion material and the dielectric material to a dielectric patterning and etching process to form a via opening region 1702 in a portion of the dielectric material and exposing a surface region 1704 of the switching material in a specific embodiment. In certain embodiments, the method can use the adhesion material as a hard mask for the dielectric patterning and etching process. Of course one skilled in the art would recognize that other variations, modifications, and alternatives can be made to these methods without departing from the scope and spirit of the invention.

As shown in FIG. 18, the method includes depositing a metal material 1802 to fill the via opening and to form a thickness of the metal material overlying the adhesion material. For amorphous silicon material as the switching material, the metal material can be silver, gold, platinum, palladium, copper, nickel, or aluminum depending on the embodiment. In a preferred embodiment, the metal material is silver for amorphous silicon switching material. The metal material maintains contact with the adhesion material free from peeling or delaminating.

In a specific embodiment, the method subjects the metal material to a patterning and etching process to form an interconnect structure for the non-volatile memory device. The metal material includes a first portion in the via opening in contact with the switching material, and a second portion overlying the adhesion material. The second portion of the metal material forms the interconnect structure for the non-volatile memory device. In a specific embodiment, the interconnect structure is elongated in shape and configured to spatially extend in a predetermined direction. Again, the interconnect structure remains in contact with the adhesion material free from peeling or delaminating in a specific embodiment.

Embodiments according to the present provide a method and a structure to form a silver wiring structure for a non-volatile memory device. The silver wiring structure further includes a portion disposed in a via opening in contact with an amorphous silicon resistive switching material. The silver wiring structure is characterized by a good adhesion to an underlying dielectric material to improve device yield and device reliability in a specific embodiment.

Though the present invention has been described using various examples and embodiments, it is also understood that the examples and embodiments described herein are for illustrative purposes only, and that various modifications or alternatives in light thereof will be suggested to persons skilled in the art and are to be included within the spirit and purview of this application and scope of the appended claims.

What is claimed is:

1. A method for forming an interconnect structure for a memory device, comprising:
providing a semiconductor substrate having a surface region;
depositing a thickness of first dielectric material overlying the surface region;
forming a plurality of first wiring structures in a portion of the first thickness of the first thickness of dielectric material, each of the plurality of first wiring structures comprising at least a surface region;
forming a switching material overlying the surface region of each of the first wiring structures;
depositing a thickness of second dielectric material overlying at least the surface region of the first plurality of first wiring structure;
depositing an adhesion material overlying the thickness of the second dielectric material;
forming a via opening in a portion of the thickness of the second dielectric material to expose a surface region of the switching material while maintaining the adhesion material overlying the second dielectric material; and
depositing a second wiring material overlying a surface region of the thickness of the second dielectric material and to fill at least part of the via opening and forming a thickness of second wiring material overlying the adhesion material while the adhesion material maintaining the second wiring material to be adhered to the surface region of the thickness of the second dielectric material.

2. The method of claim 1, further comprising forming a plurality of second wiring structures from at least the second wiring material using a patterning and etching process.

3. The method of claim 2 wherein the second wiring structure maintains bonded with the second dielectric material.

4. The method of claim 1 wherein each of the plurality of first wiring structures is spatially oriented in a first direction, and each of the plurality of second wiring structures is spatially oriented in a second direction, the second direction being perpendicular to the first direction.

5. The method of claim 1 wherein the semiconductor substrate is a single crystal silicon wafer, a silicon on oxide (SOI) substrate, or a silicon germanium material, or a combination thereof.

6. The method of claim 1 wherein the first dielectric material is silicon oxide, silicon nitride, a high K dielectric material, a low K dielectric material, or a dielectric stack including alternating layers of silicon oxide and silicon nitride (ONO stack), and a combination thereof.

7. The method of claim 1 wherein each of the plurality of first wiring structures comprises copper, tungsten, aluminum, or silver.

8. The method of claim 1 wherein each of the plurality of first wiring structures further comprises a first adhesion layer to promote adhesion between the first wiring material and the first dielectric material.

9. The method of claim 1 wherein the switching material comprises an amorphous silicon material.

10. The method of claim 1 further comprises forming a contact material comprises a p+ polysilicon material between the switching material and the first wiring structure.

11. The method of claim 1 wherein the second dielectric material is silicon oxide, silicon nitride, a high K dielectric material, a low K dielectric material, or a dielectric stack including alternating layers of silicon oxide and silicon nitride (ONO stack), and a combination thereof.

12. The method of claim 1 wherein the adhesion material comprises a titanium material, a titanium nitride material overlying a titanium material (Ti/TiN), a tantalum overlying titanium material (Ti/Ta), a tantalum nitride overlying a titanium material (Ti/TaN), a tungsten nitride overlying titanium material (Ti/WN), or a titanium tungsten overlying a titanium material (Ti/TiW), or a combination thereof.

13. The method of claim 1 wherein the second wiring structure comprises a metal material selected from silver, aluminum, gold, palladium, nickel and platinum.

14. The method of claim 1 wherein the second wiring structure comprises silver, or a silver alloy wherein silver is more than 90% of the composition.

15. The method of claim 1 wherein the metal material forms a metal region in a portion of the resistive switching material upon application of a positive bias voltage to the second wiring structure.

16. The method of claim 15 wherein the metal region comprises a filament structure extending towards the first wiring structure, the filament structure is characterized by a length dependent on at least an operating voltage comprising a write voltage and an erase voltage.

17. A method of forming an interconnect for a non-volatile memory device, comprising:
providing a switching material comprising an amorphous silicon material;
forming a thickness of a dielectric material overlying the switching material;
depositing an adhesion material overlying the thickness of the dielectric material forming a via opening in a first portion of the thickness of the dielectric material to expose a surface region of the switching material while the adhesion material remained overlying a second portion of the thickness of dielectric material;
depositing a metal material to fill the via and to form a thickness of metal material overlying the adhesion material, the metal material being in contact with the switching material; and
subjecting the metal material to a patterning and etching process to form an interconnect structure and maintaining the metal material in the via opening to be in contact with the switching material and the metal material to be in contact with the adhesion material.

18. The method of claim 17 wherein the thickness of the dielectric material comprises silicon oxide, silicon nitride, a dielectric stack comprising alternating layer of silicon oxide and silicon nitride (ONO), a low K dielectric, or a high K dielectric and a combination thereof.

19. The method of claim 17 wherein the adhesion material comprises titanium.

20. The method of claim 17 wherein the adhesion material comprises titanium nitride overlying titanium.

21. The method of claim 17 wherein the adhesion material comprises a titanium material, a titanium nitride material overlying a titanium material (Ti/TiN), a tantalum overlying titanium material (Ti/Ta), a tantalum nitride overlying a titanium material (Ti/TaN), a tungsten nitride overlying titanium material (Ti/WN), or a titanium tungsten overlying titanium material (Ti/TiW), or a combination thereof.

22. The method of claim 17 wherein forming the via opening comprises a dielectric patterning and etching process.

23. The method of claim 17 wherein the metal material is characterized by a diffusivity in the switching material in a presence of an electric field.

24. The method of claim 23 wherein the metal material is silver, gold, platinum, palladium, copper, nickel, or aluminum.

25. The method of claim 17 wherein the metal material is silver.
